(19) United States
(12) Patent Application Publication
(10) Pub. No.: US 2023/0389202 A1
(43) Pub. Date: Nov. 30, 2023

(54) CASE

(71) Applicant: Murata Manufacturing Co., Ltd., Nagaokakyo-shi (JP)

(72) Inventor: Kiyoyuki NAKAGAWA, Nagaokakyo-shi (JP)

(21) Appl. No.: 18/231,859

(22) Filed: Aug. 9, 2023

Related U.S. Application Data
(63) Continuation of application No. PCT/JP2022/007018, filed on Feb. 21, 2022.

(30) Foreign Application Priority Data
Feb. 26, 2021 (JP) 2021-030245

(51) Int. Cl. H05K 5/02; H05K 13/02

(52) U.S. Cl. CPC H05K 5/0217; H05K 13/02

(57) ABSTRACT

A case includes a case body detachably set on a feeder, a shutter slidable to open and close a discharge port, and a slider integrally provided with the shutter on an interior of the case body. The slider includes an operating hole including an elongated hole into which, in a state in which the case body is set on the feeder, a drive pin can be inserted, and extending along a reciprocal movement direction of the drive pin. The case body includes an exposing hole to expose the operating hole to outside. The drive pin is inserted into the operating hole via the exposing hole and is reciprocally movable to cause the slider to slide to open or close the discharge port via the shutter.

### CROSS REFERENCE TO RELATED APPLICATIONS

This application claims the benefit of priority to Japanese Patent Application No. 2021-030245 filed on Feb. 26, 2021 and is a Continuation Application of PCT Application No. PCT/JP2022/007018 filed on Feb. 21, 2022. The entire contents of each application are hereby incorporated herein by reference.

### BACKGROUND OF THE INVENTION

### 1. Field of the Invention

The present invention relates to a case to house electronic components such as chip components.

### 2. Description of the Related Art

When mounting electronic components on a board, a mounting device is used which mounts each of the electronic components at a predetermined position on the board.

It is necessary to supply electronic components individually to such a mounting device.

For example, Japanese Unexamined Patent Application, Publication No. 2009-295618 discloses a case in which electronic components in a loose state are collectively housed, and the electronic components are dropped onto a feeder by their own weight from a take-out port at a bottom portion.

The electronic components are individually supplied to the mounting device by the feeder.

When the case is set to the feeder and the electronic components discharged from the case by the feeder are supplied to the mounting device, it is preferable to provide a mechanism for opening and closing the component discharge port of the case in the feeder because the automatic control progresses.

However, considering that the case and the feeder are accurately associated with each other, there is a concern that the mechanism becomes complicated.

### SUMMARY OF THE INVENTION

Preferred embodiments of the present invention provide cases that each enable an opening/closing mechanism of a component discharge port to correspond to a mechanism of a feeder with a simple configuration.

A case according to a preferred embodiment of the present invention is settable to a feeder including a drive pin that moves reciprocally, the case including a case body that includes a housing space to house a plurality of components and a discharge port to discharge the plurality of components housed in the housing space, the case body being settable to the feeder in a detachable manner, a shutter to open and close the discharge port by sliding, and a slider integral with the shutter and inside the case body, the slider including an operation hole with a size such that, while the case body is set to the feeder, the drive pin is insertable into the operation hole, and while the drive pin is inserted into the operation hole, the drive pin is movable reciprocally, the case body including an exposure hole that enables the operation hole to be exposed to outside, wherein the drive pin that is insertable into the operation hole via the exposure hole and movable reciprocally to enable the slider to slide to enable the shutter to open and close the discharge port.

According to preferred embodiments of the present invention, cases are provided that each enable an opening/closing mechanism of a component discharge port to correspond to a mechanism of a feeder with a simple configuration.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a side view showing the interior of a case according to a preferred embodiment of the present invention.

FIG. 2 is a front view of a case according to a preferred embodiment of the present invention.

FIG. 3 is a bottom view of a case according to a preferred embodiment of the present invention.

FIG. 4 is an enlarged side view showing an interior of a front portion of a case according to a preferred embodiment of the present invention.

FIGS. 5A to 5E are diagrams showing an operation in which a case according to a preferred embodiment of the present invention is set to the feeder in the order of 5A to 5E.

FIGS. 6A to 6E are diagrams showing an operation whereby a case according to a preferred embodiment of the present invention is set to the feeder of the modified example in the order of 5A to 5E.

### DETAILED DESCRIPTION OF THE PREFERRED EMBODIMENTS

Hereinafter, preferred embodiments of the present invention will be described with reference to the drawings.

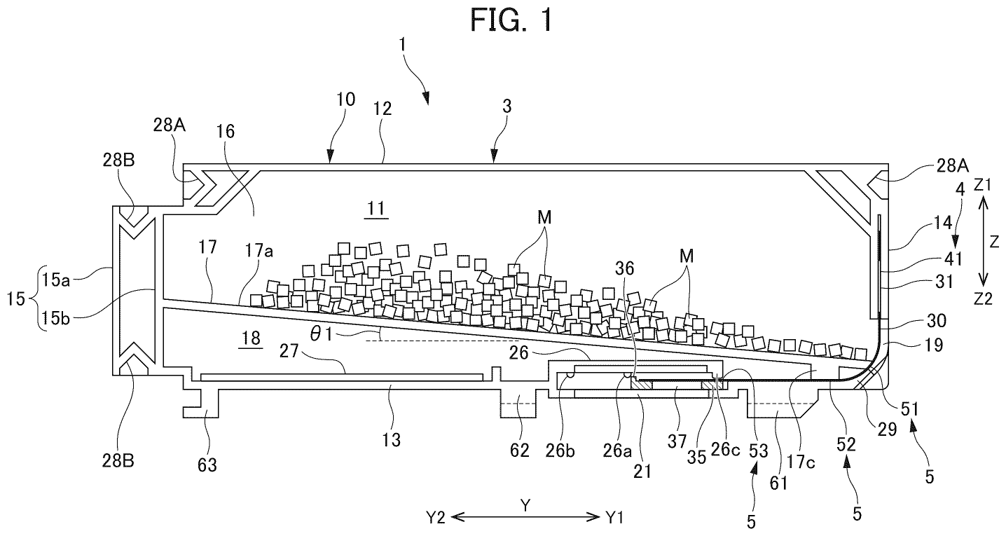

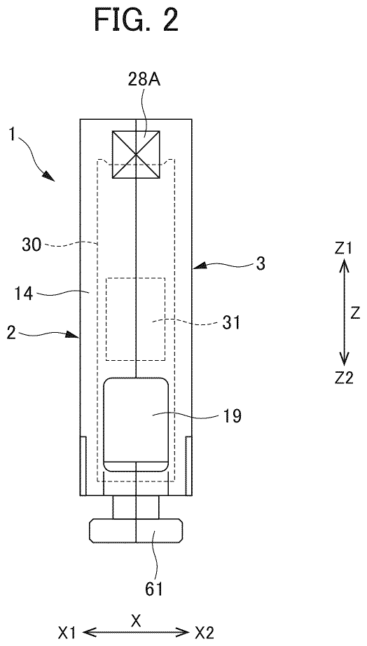

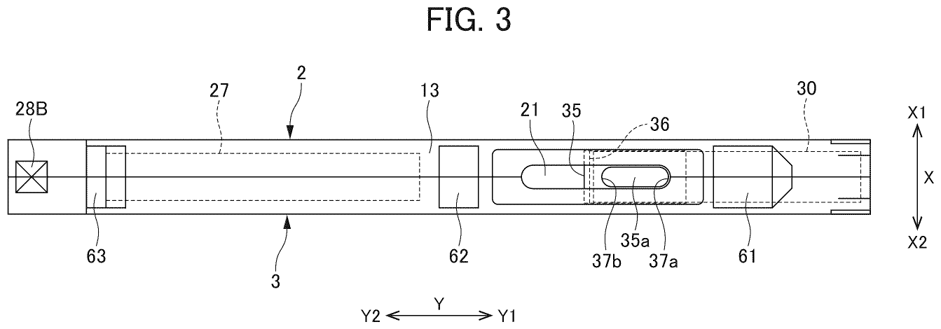

FIG. 1 is a side view of the interior of a case 1 according to a preferred embodiment of the present invention. FIG. 2 is a front view of the case 1 viewed from the front. FIG. 3 is a bottom view of the case 1.

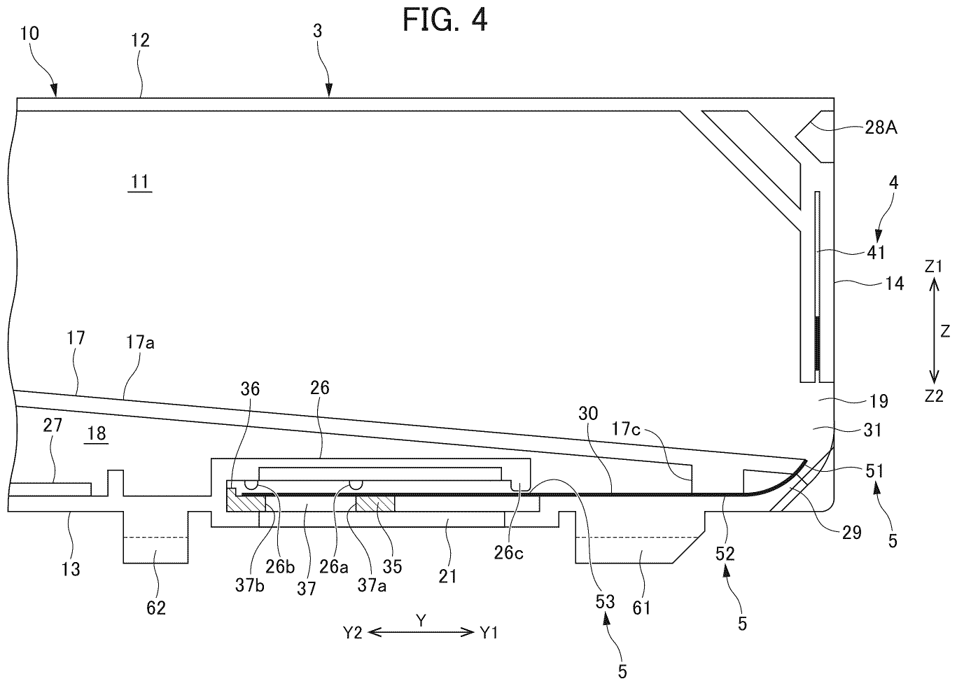

FIG. 4 is an enlarged side view showing the interior of the front portion of the case 1.

As shown in FIG. 1, the case 1 houses therein a plurality of electronic components M (shown in FIG. 1) as components in a loose state.

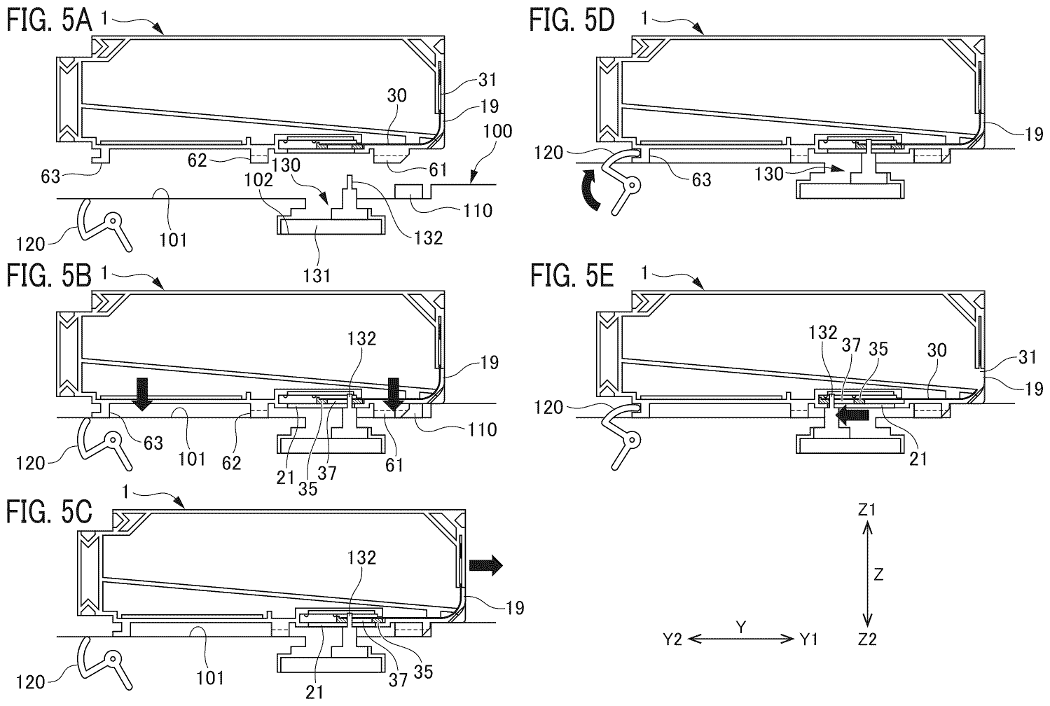

The case 1 including a plurality of electronic components M is detachably set in a feeder 100, as shown in FIG. 5.

The feeder 100 discharges the electronic components M from the case 1 using vibration, and supplies the electronic components M to a mounting device (not shown).

Each of the electronic components M of the present preferred embodiment is, for example, a small rectangular parallelepiped electronic component having a length of about 1.2 mm or less in the longitudinal direction.

Examples of such electronic components include capacitors and inductors, but the present preferred embodiment is not limited thereto.

Arrows X, Y, and Z shown in any one of FIGS. 1, 2, and 3 respectively indicate the lateral (left-right) direction, the longitudinal (front-rear) direction, and the vertical (up-down) direction of the case 1 when the case 1 is set in the feeder 100.

Furthermore, the left side in the lateral direction X is denoted by X1, the right side is denoted by X2, the front side in the longitudinal direction Y is denoted by Y1, the rear side is denoted by Y2, the upper side in the vertical direction Z is denoted by Z1, and the lower side is denoted by Z2.

Also in FIGS. 4 to 6, the lateral direction X, the longitudinal direction Y, and the vertical direction Z are similarly applied.

The lateral direction, the longitudinal direction, and the vertical direction in the following description are based on the directions indicated by the arrows.

As shown in FIGS. 2 and 3, the case 1 includes a first member 2 and a second member 3 divided from each other in the lateral direction.

The first member 2 and the second member 3 are joined to each other to provide the case 1.

FIG. 1 shows a state in which there is no first member 2 on the left side, and shows the interior of the second member 3 on the right side.

The case 1 has a flat box shape that is long in the longitudinal direction and thin in the lateral direction.

In the following description, except where necessary, the first member 2 and the second member 3 are not individually described, and the configuration in which the first member 2 and the second member 3 are joined to each other will be described.

As shown in FIG. 1, the case 1 includes a case body 10 that houses the plurality of electronic components M, and a shutter 30 that opens and closes a discharge port 19 of the case body 10.

The case body 10 includes a housing space 11 to house the plurality of electronic components M in a loose state.

The case body 10 includes a top plate portion 12 and a bottom plate portion 13 which extend in the longitudinal direction, a front wall portion 14 and a rear wall portion 15 which extend in the vertical direction, a pair of left and right side wall portions 16, and an sloped plate portion 17 which partitions the interior of the case body 10 vertically.

The rear wall portion 15 includes an outer rear wall portion 15a defining and functioning as an outer surface and an inner rear wall portion 15b in front of the outer rear wall portion.

The discharge port 19 is provided at the lower portion of the front wall portion 14.

As shown in FIG. 2, the discharge port 19 is a rectangular or substantially rectangular opening.

The discharge port 19 is not limited to a rectangular or substantially rectangular shape, and may be, for example, an opening having a circular or substantially circular shape, an elliptical or substantially elliptical shape, or the like.

The discharge port 19 is opened and closed by a shutter 30 described later.

The sloped plate portion 17 extends between the left and right side wall portions 16 and extends from the inner rear wall portion 15b to the lower portion of the discharge port 19.

The sloped plate portion 17 is provided below the center of the interior of the case body 10 in the vertical direction.

In the case body 10, the upper side of the sloped plate portion 17 defines and functions as the housing space 11, and the lower side of the sloped plate portion 17 defines and functions as a lower space 18.

The sloped plate portion 17 is sloped at a downward gradient toward the discharge port 19, and an upper surface of the sloped plate portion 17 is a sloped surface 17a which is sloped at a downward gradient toward the discharge port 19.

In this preferred embodiment, the slope angle θ1 of the sloped surface 17a is, for example, about 10° with respect to the horizontal direction when the case 1 is set to the feeder 100.

The slope angle θ1 of the sloped surface 17a is, for example, preferably about 3° or more and about 10° or less.

The slope angle θ1 of the sloped surface 17a is appropriately adjusted according to a vibration condition described later.

The shutter 30 slides to open and close the discharge port 19.

The shutter 30 continuously extends from the bottom plate portion 13 to the front wall portion 14, and is slidable along the extending direction.

The shutter 30 is an elongated strip-shaped film.

The shutter 30 is made of, for example, a bendable and flexible material having a certain degree of rigidity such as PET (Polyethylene terephthalate).

The width of the shutter 30 is slightly larger than the width of the discharge port 19, and has a width capable of covering the discharge port 19 without ant gap.

As shown in FIGS. 1 and 2, an opening 31 having the same or substantially the same shape as the discharge port 19 is provided in the front end portion of the shutter 30.

The shutter 30 can slide along the lower guide portion 5 and the upper guide portion 4 of the case body 10.

The lower guide portion 5 is provided above the bottom plate portion 13, and the upper guide portion 4 is provided above the discharge port 19.

The rear side of the shutter 30 slides horizontally or substantially horizontally along the lower guide portion 5, and the front side of the shutter 30 slides vertically or substantially vertically along the upper guide portion 4.

Each of the lower guide portion 5 and the upper guide portion 4 provides a passage to slidably hold the shutter 30 while maintaining the surface direction of the shutter 30 along the lateral direction.

As shown in FIGS. 1 and 4, a slider 35 to slide the shutter 30 to open and close the discharge port 19, is provided at the rear end of the shutter 30.

The slider 35 is integrally fixed to the lower surface of the shutter 30.

As shown in FIG. 3, the slider 35 is a rectangular or substantially rectangular plate piece elongated in the longitudinal direction.

The slider 35 includes an operation hole 37 of an elongated hole extending in the longitudinal direction.

The operation hole 37 is an oblong through hole having a length in the longitudinal direction longer than the length in the lateral direction.

The length in the longitudinal direction of the operation hole 37 is set such that a cylindrical drive pin 132, which will be described later, is movable reciprocally. The length in the longitudinal direction of the operation hole 37 is set to be, for example, about 3 times or more and 5 times or less the length of the drive pin 132 in the longitudinal direction, i.e., the outer diameter.

Preferably, the length in the longitudinal direction is, for example, about 10% larger than the sliding distance when the case 1 is fixed as described later.

The slider 35 is provided inside the case body 10, and slides on the upper surface of the bottom plate 13 in the longitudinal direction.

In the range in which the shutter 30 slides, when the opening 31 coincides with the discharge port 19, the discharge port 19 opens, and when the opening 31 is provided above the discharge port 19, the discharge port 19 is closed by the shutter 30.

As shown in FIGS. 3 and 4, the slider 35 includes a front edge 37a and a rear edge 37b at a front edge and a rear edge of an inner peripheral edge of the operation hole 37, respectively.

The bottom plate portion 13 of the case body 10 includes an exposure hole 21 to expose the operation hole 37 of the slider 35 to the outside.

The exposure hole 21 has a size such that the entire or substantially the entire operation hole 37 is always exposed at least from a position where the slider 35 slides forward and the discharge port 19 is closed by the shutter 30 to a position where the slider 35 slides rearward and the opening 31 coincides with the discharge port 19 and the discharge port 19 is opened.

The exposure hole 21 is a long hole elongated in the longitudinal direction, and has a length including, for example, about 0% to about 10% of a sliding distance when the case 1 is fixed in addition to a distance from a position where the shutter 30 closes the discharge port 19 to a position where the discharge port 19 opens.

The slider 35 includes a stopper 36 to position the slide position of the shutter 30 at two positions, i.e., a position where the opening 31 of the shutter 30 coincides with the discharge port 19 and the discharge port 19 is opened, and a position where the opening 31 moves above the discharge port 19 and the shutter 30 closes the discharge port 19.

As shown in FIG. 4, the stopper 36 includes a protruding portion which is provided at the rear end portion on the upper surface of the slider 35 and protrudes upward.

As shown in FIG. 4, a plate portion 26 is provided in the lower space 18 such that a space in which the slider 35 is provided is provided between the bottom plate portion 13 and the plate portion 26.

The plate portion 26 is provided integrally with the bottom plate portion 13.

A front protruding portion 26a and a rear protruding portion 26b each protruding downward are provided as a pair in the longitudinal direction at a rear side on the lower surface of the plate portion 26.

A guide protrusion 26c of a first lower guide portion 51 described later is provided at a front end portion on the lower surface of the plate portion 26.

The stopper 36 engages with one of the front protruding portion 26a and the rear protruding portion 26b.

When the slider 35 moves forward and the stopper 36 engages with the front protruding portion 26a, as shown in FIG. 1, the opening 31 is positioned at the front wall portion 14 above the discharge port 19, and the discharge port 19 is closed by the shutter 30.

When the slider 35 moves rearward and the stopper 36 engages with the rear protruding portion 26b, the opening 31 coincides with the discharge port 19, and the discharge port 19 is opened as shown in FIG. 4.

The electronic components M housed in the housing space 11 pass through the open discharge port 19 and are discharged from the case 1.

The slider 35 is slid by the drive pin 132 included in the feeder 100 described later.

As shown in FIG. 4, the lower guide portion 5 includes a first lower guide portion 51 provided below the discharge port 19, a second lower guide portion 52 provided behind the first lower guide portion 51, and a third lower guide portion 53 provided behind the second lower guide portion 52.

The third lower guide portion 53 includes the guide protrusion 26c provided at the front end portion on the lower surface of the plate portion 26.

The second lower guide portion 52 includes a slit provided between a protruding portion 17c that protrudes downward at the front end portion of the sloped plate portion 17 and the bottom plate portion 13.

The first lower guide portion 51 includes a front end surface of the sloped plate portion 17 and a front end portion 29 of the bottom plate portion 13.

The shutter 30 slides on the lower surface of the guide protrusion 26c in the third lower guide portion 53 and passes through the slit provided between the protruding portion 17c and the bottom plate portion 13 in the second lower guide portion 52. With such a configuration, the rear side of the shutter 30 slides in the longitudinal direction immediately above the bottom plate portion 13.

In the first lower guide portion 51, the shutter 30 slides along the front end portion 29 of the bottom plate portion 13 which curves concavely in the longitudinal direction, and further slides along the front end surface of the sloped plate portion 17, such that the shutter 30 bends upward at an angle of, for example, approximately 90° from the horizontal direction, and is converted into a posture extending in the vertical direction.

The shutter 30 slides in the vertical direction above the third lower guide portion 53.

As shown in FIG. 4, the upper guide portion 4 includes a slit 41 provided in the front wall portion 14 and extending in the vertical direction.

The front end portion of the shutter 30 enters the slit 41 from the lower end of the front wall portion 14, and slides in the slit 41.

As shown in FIG. 1, the band-shaped RFID tag 27 elongated in the longitudinal direction is provided at a rear portion of the lower space 18.

The RFID tag 27 has, for example, a sticker shape and is attached to the upper surface of the bottom plate portion 13.

The RFID tag 27 has a publicly known configuration including a transmission/reception unit, memory, an antenna, and the like.

A reader/writer (not shown) to read and write information from and to the RFID tag 27 is provided in the feeder 100.

The case body 10 includes upper grip portions 28A and rear grip portions 28B.

The upper grip portions 28A are a pair of front and rear depressions provided at both front and rear ends of the upper side of the case body 10.

The rear grip portions 28B are a pair of upper and lower depressions provided at both upper and lower ends of the rear side of the case body 10.

Each of the upper grip portions 28A and the rear grip portions 28B is gripped by the robot hand, for example, when the case 1 is transported by the robot hand.

As shown in FIG. 1, the case 1 includes a plurality of claw portions on the bottom surface to detachably set the case 1 in the feeder 100.

In the present preferred embodiment, a first claw portion 61, a second claw portion 62, and a third claw portion 63 are provided on the bottom surface at intervals in the longitudinal direction.

Each of the first claw portion 61, the second claw portion 62, and the third claw portion 63 is provided integrally with the case body 10.

Each of the first claw portion 61 and the second claw portion 62 includes a T-shaped slot having an inverted T-shape in a cross section in a plane extending in the up, down, left, and right directions.

The third claw portion 63 is an L-shaped plate piece extending rearward in a side view.

As shown in FIG. 5, the feeder 100 includes a set surface 101 on which the case 1 is placed and set.

At the front side of the set surface 101, a pressing portion 110 is provided in which the first claw portion 61 is inserted and engaged from the rear to position the case 1.

A lock lever 120 that engages with the third claw portion 63 from the rear side by rotating is rotatably provided at a rear lower portion of the set surface 101.

A recess 102 is provided at the front side of the set surface 101 and at the rear side of the pressing portion 110, and an opening/closing mechanism 130 to slide the shutter 30 is provided in the recess 102.

The opening/closing mechanism 130 includes a base portion 131 provided on the bottom surface of the recess 102, and a drive pin 132 provided so as to be movable in the longitudinal direction on the base portion 131.

The drive pin 132 has a cylindrical or substantially cylindrical shape and protrudes upward from the set surface 101.

The drive pin 132 is supported to be movable in the longitudinal direction along a guide groove provided in the base portion 131, for example, and is driven in the longitudinal direction by an actuator or the like.

The feeder 100 vibrates the case 1 set on the set surface 101.

Vibration is applied to the feeder 100 by a vibrator (not shown).

Examples of the vibrator include, for example, a triaxial vibrator which applies three-dimensional vibrations in the longitudinal direction and the vertical direction to the feeder 100.

Due to the vibration, the electronic components M moves down the sloped surface 17a and are discharged from the discharge port 19.

The case 1 is set to the feeder 100 in the following manner, and the shutter 30 is opened and closed by the opening/closing mechanism 130.

As shown in FIG. 5A, the drive pin 132 of the feeder 100 is positioned at the front side.

Then, the case 1 in which the discharge port 19 is closed by the shutter 30 is provided above the feeder 100 and lowered therefrom, and as shown in FIG. 5B, the first claw portion 61, the second claw portion 62, and the third claw portion 63 are respectively placed on the set surface 101.

At this time, the first claw portion 61 is positioned rearward of the pressing portion 110, and the distal end of the drive pin 132 is inserted into the operation hole 37 of the slider 35 through the exposure hole 21 of the case 1.

Next, as shown in FIG. 5C, the case 1 is slid forward by a predetermined distance (for example, about 6 mm) on the set surface 101, and the first claw portion 61 engages with the pressing portion 110, such that the longitudinal direction and the vertical direction are positioned.

The drive pin 132 approaches or contacts the rear edge 37b shown in FIGS. 3 and 4 in the operation hole 37 of the slider 35 moved forward.

Next, as shown in FIG. 5D, the lock lever 120 is rotated to engage with the third claw portion 63, such that the case 1 is fixed to the feeder 100.

Next, as shown in FIG. 5E, the drive pin 132 moves rearward by a predetermined distance (for example, about 10 mm).

The drive pin 132 contacts the rear edge 37b of the operation hole 37 of the slider 35, and pushes the slider 35 rearward to slide the slider 35.

When the slider 35 slides rearward, the shutter 30 slides rearward together therewith, and the opening 31 coincides with the discharge port 19 to open the discharge port 19.

Thereafter, the feeder 100 vibrates, and the electronic components M housed in the case 1 move down the sloped surface 17a, are discharged from the discharge port 19, and are supplied to the mounting device.

When the supply of the electronic components M is completed, the case 1 is detached from the feeder 100.

The detachment of the case 1 is performed in the reverse of the setting operation described above.

That is, first, the drive pin 132 is advanced to push the front edge 37a of the operation hole 37 of the slider 35 forward, thereby advancing the slider 35.

With such a configuration, the discharge port 19 is closed by the shutter 30.

Next, after the lock lever 120 is released, the case 1 is retracted to the position shown in FIG. 5B, and the case 1 is removed upward from the feeder 100 as shown in FIG. 5A.

When the supply of the electronic components M is completed or when it is necessary to remove the case 1 during the supply of the electronic components M, the case 1 can be removed from the feeder 100 by releasing the lock lever 120 and moving the case 1 upward while the position of the drive pin 132 remains unchanged.

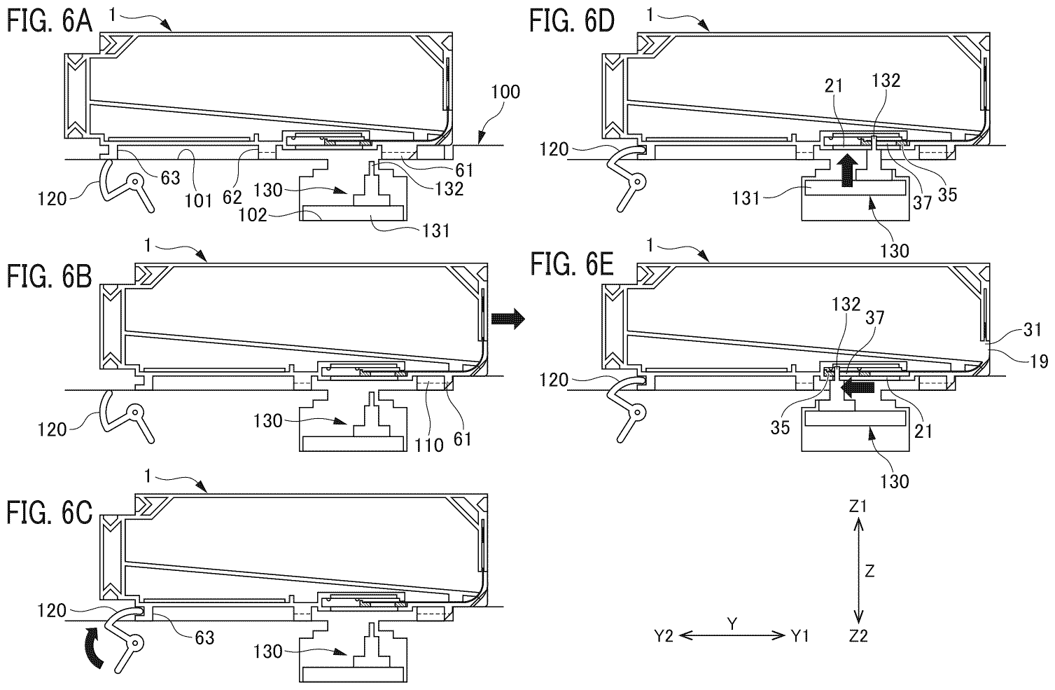

FIG. 6 shows a modified example of the feeder 100.

The feeder 100 shown in FIG. 6 is different from the feeder 100 shown in FIG. 5 in that the opening/closing mechanism 130 is vertically movable.

The recess 102 in which the opening/closing mechanism 130 is housed is deeper than the feeder 100 shown in FIG. 5, and when the opening/closing mechanism 130 rises, the drive pin 132 protrudes upward above the set surface 101, and is inserted into the operation hole 37 of the slider 35.

According to the feeder 100 shown in FIG. 6, the case 1 is set to the feeder 100 in the following manner, and the shutter 30 is opened and closed by the opening/closing mechanism 130.

As shown in FIG. 6A, the opening/closing mechanism 130 is lowered to the bottom surface of the recess 102, and the drive pin 132 is positioned at the front side.

Then, the case 1 in which the discharge port 19 is closed by the shutter 30 is placed on the set surface 101.

Next, as shown in FIG. 6B, the case 1 is slid forward by a predetermined distance (for example, about 10 mm) on the set surface 101, and the first claw portion 61 engages with the pressing portion 110.

Next, as shown in FIG. 6C, the lock lever 120 is rotated to engage with the third claw portion 63, such that the case 1 is fixed to the feeder 100.

Next, as shown in FIG. 6D, the opening/closing mechanism 130 is raised by a predetermined distance (for example, about 7 mm), and the distal end of the drive pin 132 is inserted into the operation hole 37 of the slider 35 through the exposed hole 21 of the case 1.

The drive pin 132 approaches or contacts the rear edge 37b of the operation hole 37 of the slider.

Next, as shown in FIG. 6E, the drive pin 132 moves rearward by a predetermined distance (for example, about 10 mm to about 16 mm).

The drive pin 132 contacts the rear edge 37b of the operation hole 37 of the slider 35, and pushes the slider 35 rearward to slide the slider 35.

When the slider 35 slides rearward, the shutter 30 slides rearward together therewith, and the opening 31 coincides with the discharge port 19 to open the discharge port 19.

Thereafter, the feeder 100 vibrates, and the electronic components M in the case 1 move down the sloped surface 17a, is discharged from the discharge port 19, and is supplied to the mounting device.

When the supply of the electronic components M is completed, the case 1 is detached from the feeder 100.

The detachment of the case 1 is performed in the reverse of the setting operation described above.

That is, first, the drive pin 132 is advanced to push the front edge 37a of the operation hole 37 of the slider 35 forward, such that the slider 35 is advanced.

With such a configuration, the discharge port 19 is closed by the shutter 30.

Next, after the opening/closing mechanism 130 is lowered and the lock lever 120 is released, the case 1 is retracted to the position shown in FIG. 6B, and the opening/closing mechanism 130 is lowered as shown in FIG. 6A.

In this state, the case 1 can be detached from the feeder 100.

When the supply of the electronic components M is completed or when it is necessary to remove the case 1 during the supply of the electronic components M, the case 1 can be removed from the feeder 100 by releasing the lock lever 120 and moving the case 1 upward while the position of the drive pin 132 remains unchanged.

With a case 1 according to a preferred embodiment described above, the following advantageous effects are achieved.

(1) A case 1 according to a preferred embodiment of the present invention is the case 1 that is settable to the feeder 100 including the drive pin 132 that moves reciprocally. The case 1 includes the case body 10 that includes the housing space 11 that houses the plurality of electronic components M and the discharge port 19 that discharges the plurality of electronic components M housed in the housing space 11. The case body 10 is settable to the feeder 100 in a detachable manner. The case body 10 further includes the shutter 30 that opens and closes the discharge port 19 by sliding and the slider 35 that is provided integrally with the shutter 30 and provided inside the case body 10. The slider 35 includes the operation hole 37 having a size such that, while the case body 10 is set to the feeder 100, the drive pin 132 is insertable into the operation hole 37, and while the drive pin 132 is inserted into the operation hole 37, the drive pin 132 is movable reciprocally. The case body 10 includes the exposure hole 21 that allows the operation hole 37 to be exposed to the outside. The drive pin 132 that is inserted into the operation hole 37 via the exposure hole 21 and moves reciprocally allows the slider 35 to slide, such that the shutter 30 opens and closes the discharge port 19.

According to a preferred embodiment, since the operation hole 37 of the slider 35 to open and close the shutter 30 is a hole having a size that allows the drive pin 132 to move reciprocally, it is possible to easily insert the drive pin 132 into the operation hole 37 when the case 1 is set to the feeder 100.

Therefore, it is possible to enable the opening/closing mechanism of the discharge port 19 of the case 1 to correspond to the mechanism of the feeder 100 with a simple configuration.

(2) In a case 1 according to a preferred embodiment, it is preferable that the operation hole 37 is an elongated hole extending in the direction in which the drive pin 132 moves reciprocally, and the exposure hole 21 has a length in the direction in which the drive pin 132 moves reciprocally longer than the length of the operation hole 37 in the same direction.

With such a configuration, it is possible to provide the operation hole 37 and the exposure hole 21 each having a minimum necessary size, and it is also possible to easily adjust the slide stroke of the slider 35 and the shutter 30 by changing the length of the operation hole 37 in the longitudinal direction.

(3) A case 1 according to a preferred embodiment includes a configuration in which the case body 10 includes the slider 35 in such that while the case body 10 is set to the feeder 100, the slider 35 is slidable in a horizontal or substantially horizontal direction and, while the case body 10 is set to the feeder 100, the drive pin 132 is insertable into the operation hole 37 from below.

With such a configuration, the case 1 and the feeder 100 can be easily made to correspond with each other, and thus, it is possible to set the case 1 to the feeder 100 reliably and easily.

(4) In a case 1 according to a preferred embodiment, it is preferable that the slider 35 includes the stopper 36 that performs positioning at two locations including the opening position where the shutter 30 opens the discharge port 19 of the case body 10, and the closing position where the shutter 30 closes the discharge port 19 of the case body 10.

With such a configuration, it is possible to position the shutter 30 at the opening position and the closing position of the discharge port 19 with high accuracy.

(5) In a case 1 according to a preferred embodiment, it is preferable that the case body 10 includes the sloped surface 17a that is sloped at a downward gradient toward the discharge port 19 while the case body 10 is set to the feeder 100, and enables the plurality of electronic components M housed in the housing space 11 to be transported to the discharge port 19.

With such a configuration, it is possible to enable the electronic components M to smoothly and reliably be transported to the discharge port 19 in the case body 10.

(6) In a case 1 according to a preferred embodiment, while the case body 10 is set to the feeder 100, the sloped surface 17a is sloped at about 3° or more and about 10° or less.

With such a configuration, it is possible to enable the electronic components M to smoothly and reliably be transported to the discharge port 19, while moving down the sloped surface 17a for transportation in the case 1.

Although preferred embodiments have been described above, the present invention is not limited to the preferred embodiments, and modifications, improvements, and the like are included in the present invention.

For example, the position of the discharge port 19 is not limited to a configuration in which the discharge port 19 is opened toward the front side, and may be a configuration in which the discharge port 19 is opened toward the bottom surface or the like, and the sliding path of the shutter 30 may be appropriately changed according to the configuration.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A case that is settable to a feeder including a drive pin movable reciprocally, the case comprising:
a case body including a housing space to house a plurality of components and a discharge port to discharge the plurality of components housed in the housing space, the case body being settable to the feeder in a detachable manner;
a shutter to open and close the discharge port by sliding; and
a slider provided integrally with the shutter and inside the case body; wherein
the slider includes an operation hole with a size such that, while the case body is set to the feeder, the drive pin is insertable into the operation hole, and while the drive pin is inserted into the operation hole, the drive pin is movable reciprocally;
the case body includes an exposure hole enabling the operation hole to be exposed to outside;
the drive pin inserted into the operation hole via the exposure hole and moving reciprocally enables the slider to slide, such that the shutter opens and closes the discharge port.

2. The case according to claim 1, wherein
the operation hole is an elongated hole extending in a direction in which the drive pin is movable reciprocally; and
the exposure hole has a length in the direction in which the drive pin moves reciprocally, which is longer than a length of the operation hole in a same direction.

3. The case according to claim 1, wherein
the case body includes the slider such that, while the case body is set to the feeder, the slider is slidable in a horizontal or substantially horizontal direction; and
while the case body is set to the feeder, the drive pin is insertable into the operation hole from below.

4. The case according to claim 1, wherein the slider includes a stopper to perform positioning at two locations including an opening position where the shutter opens the discharge port of the case body, and a closing position where the shutter closes the discharge port of the case body.

5. The case according to claim 1, wherein the case body includes a sloped surface with a downward gradient sloped toward the discharge port while the case body is set to the feeder, and enables the plurality of components housed in the housing space to be transported to the discharge port.

6. The case according to claim 5, wherein, while the case body is set to the feeder, the sloped surface is sloped at about 3° or more and about 10° or less.

7. The case according to claim 1, wherein each of the plurality of components is a rectangular or substantially rectangular parallelepiped electronic component having a length of about 1.2 mm or less.

8. The case according to claim 1, wherein each of the plurality of components is a capacitor or an inductor.

9. The case according to claim 1, wherein the discharge port includes a rectangular or substantially rectangular opening.

10. The case according to claim 1, wherein the shutter includes an elongated strip-shaped film.

11. The case according to claim 1, wherein the shutter is made of polyethylene terephthalate.

12. The case according to claim 1, wherein a width of the shutter is larger than a width of the discharge port.

13. The case according to claim 1, wherein the shutter includes an opening with a same or substantially a same shape as a shape of the discharge port.

14. The case according to claim 1, wherein the slider is provided at a rear end of the shutter.

15. The case according to claim 15, wherein the length of the exposure hole is about 0% to about 10% of a sliding distance when the case is fixed.
